(19) United States
(12) Patent Application Publication
(10) Pub. No.: US 2004/0048194 A1
(43) Pub. Date: Mar. 11, 2004

(54) Mehod for forming a tunable deep-ultraviolet dielectric antireflection layer for image transfer processing

(75) Inventors: Gregory Breyta, San Jose, CA (US); Mark W. Hart, San Jose, CA (US); William D. Hinsberg, Fremont, CA (US); Alfred F. Renaldo, San Jose, CA (US)

Correspondence Address: ALTERA LAW GROUP, LLC, 6500 CITY WEST PARKWAY, SUITE 100, MINNEAPOLIS, MN, 55344-7704, US

(73) Assignee: International Business Machines Corporation, Armonk, NY (US)

(21) Appl. No.: 10/241,137

(22) Filed: Sep. 11, 2002

(51) Int. Cl. G03F 7/11; G03F 7/16; G03F 7/20; G03F 7/26; G03F 7/38; G11B 5/127

(52) U.S. Cl. 430/271.1; 430/327; 430/311; 430/315; 430/950; 430/296; 430/319; 430/320; 360/110

(57) ABSTRACT

A tunable dielectric antireflective layer for use in photolithographic applications, and specifically, for use in an image transfer processing. The tunable dielectric antireflective layer provides a spin-on-glass (SOG) material that can act as both a hardmask and a deep UV antireflective layer (BARC). One such material is titanium oxide generated by spin-coating a titanium alkanate and curing the film by heat or electron beam. The material can be “tuned” to match index of refraction (n) with the index of refraction for the photoresist and also maintain a high absorbency value, k, at a specified wavelength. A unique character of the tunable dielectric antireflective layer is that the BARC/hardmask layer allows image transfer with deep ultraviolet photoresist.

### BACKGROUND OF THE INVENTION

1. Field of the Invention.

The present invention relates to photolithographic techniques used in image transfer processing. More particularly, the present invention relates to a tunable deep-ultraviolet (DUV) dielectric antireflective layer.

2. Description of Related Art.

Lithography is one of the most critical operations in thin film processing. For example, small, precisely formed structures such as Thin Film Heads (TFH), as used in the magnetic storage industry, are formed using lithographic techniques. Techniques, such as deep-ultraviolet (DUV) lithography, have been developed to scale minimum feature sizes of devices to sub-half-micron dimensions. Nevertheless, manufacturers continuously strive to create higher precision features by achieving better linewidth control, thereby realizing designs that were previously impossible.

Typically, the lithographic technique deposits alternating layers of conductive and insulating materials onto a substrate by evaporation, sputtering, plating, or other deposition technique that provides precise control of the deposition thickness. Chemical etching, reactive ion etching (RIE), or other mechanisms shape and form the deposited layers into features, such as pole-tip assemblies of thin film heads, having the desired precision. Although existing lithographic techniques work sufficiently well to provide such structures, with feature sizes suitable for current data storage capacity, these lithographic techniques are limited as to the small feature sizes that they can produce.

Thin film structures require sharply defined photoresist patterns because these patterns are used to define the locations (and density) of structures formed. In a thin film process, a thin layer of photoresist may be applied to the surface of a wafer. The wafer is heated in a process called soft baking, wherein partial evaporation of photoresist solvents takes place. A mask is then aligned over the wafer, wherein the mask allows light to pass through its clear areas and be blocked by opaque areas during a light exposure step. However, during the exposure step, light may reflect from the surface of an underlying substrate (or neighboring features) over which the photoresist is formed. For example, materials that are used to form the thin film head structure are highly reflective, e.g., copper, tantalum and alloys of nickel, iron and cobalt. Reflections from the surface of the substrate underlying the photoresist causes deleterious effects that limit the resolution of photolithographic photoresist patterning.

These deleterious effects are caused by light passing through the photoresist at least twice, rather than only once. This occurs because light is reflected from a surface of the underlying substrate and components (or features) and passes back through the photoresist layer a second time. Accordingly, the chemical structure of the photoresist changes differently when light passes through the photoresist more than once. A portion of the light, already reflected from the surface of the underlying substrate can also reflect again from the surface of the photoresist, passing back through the photoresist yet again. In fact, standing light waves can result in the photoresist from superpositioning of incident and reflected light rays. These reflections result in process latitude and control problems.

The reflection of the light reduces the sharpness of the resulting photoresist pattern. A portion of the light reflected obliquely from the surface of the underlying substrate can also be again reflected obliquely from the surface of the photoresist. As a result of such angular reflections, the light can travel well outside those photoresist regions underlying the transmissive portions of the photolithographic mask. This potentially causes photoresist exposure well outside those photoresist regions underlying transmissive portions of the photolithographic mask. Exposure outside the photoresist region results in a less sharply defined photoresist pattern that limits the density of structures formed.

More particularly, as linewidths decrease, the use of shorter-wavelength light in projection tools becomes indispensable. However, the reflectivity at the interface between the photoresist and the substrate increases as the wavelength decreases. This increase in reflectivity causes a critical dimension variation that is due to multiple interference effects as well as the reflection from the substrate topography as discussed earlier.

Variations in the photoresist layer thickness cause variations in the critical dimension of desired structures to be formed, otherwise known as the swing curve effect. In addition, notching may occur due to reflectivity from substrates having a varied topology. Notching may cause poor image resolution when light is reflected from the edges and slopes of the varying topology into regions that are intended to be unexposed. Thus, notching and swing effects, which will be discussed in more detail below, are significantly enhanced in the lithographic process.

In current image transfer processes, highly etch resistant metals such as tantalum oxide, titanium nitride, tungsten or silicon and their oxides, can act as conventional metal oxide hardmasks and their oxides, which exhibit highly reflective qualities at deep-UV wavelengths. Moreover, these metals require deposition tools (e.g., sputtered target or CVD), which can be costly as well as creating a time-consuming process.

A common method to address problems occurring from such highly reflective surfaces is to apply a top antireflective coating (TARC) or a bottom anti-reflective coating (BARC). Although a TARC can significantly reduce the swing effect by reducing the reflectivity at the air-photoresist interface, the TARC does not reduce the notching problem. However, a BARC could eliminate both the swing and notching problems in the lithography process and become the most complete solution to obtaining a high resolution in deep-UV lithography. This BARC solution is realized because a BARC layer minimizes reflected light during a photoexposure step, thereby resulting in more faithfully reproduced linewidth.

However, an increase in reflectivity at interfaces between the BARC layer and another layer, such as a photoresist layer, occurs due to a mismatch between the refractive index of each layer. Accordingly, anti-reflective layers still need to be fine-tuned to minimize reflection. An anti-reflection layer needs to be optimized together with the photoresist to reduce unwanted reflectivity. This material requires adequately high absorpancy (k), along with a close matching of refractive indexes (n) between layers minimizes the reflection of light between the layers and also minimizes bending of light rays passing from one layer into another (refraction). In addition, the thickness of the layers of the anti-reflective coating must be precisely controlled to obtain proper absorption of the reflected light in a particular application.

An additional problem is that, after photoresist exposure, a BARC must be cleared from the developed-away regions of the photoresist without leaving undesired side-effects such as re-depositing non-volatile BARC-byproducts on the photoresist sidewalls, thereby consuming some of the critical dimension (CD) budget.

It can be seen that there is a need to tune an anti-reflective layer to have an index of refraction that matches that of a conventional photoresist to minimize reflection.

It can also be seen then that there is a need to create an effective anti-reflective layer making subsequent lithographic processing easier.

### SUMMARY OF THE INVENTION

To overcome the limitations in the prior art described above, and to overcome other limitations that will become apparent upon reading and understanding the present specification, the present invention discloses a method for forming a tunable DUV antireflective layer and a structure thereof.

The present invention solves the above-described problems by providing a spin-on-glass (SOG) material that can act as both a hardmask and a deep-UV antireflective layer (BARC). One such SOG material is titanium oxide generated by spin-coating an alkyl titanate and curing the film by heat or electron beam. The material can be “tuned” to match index of refraction (n) of an anti-reflective layer with the index of refraction for a photoresist, and also maintain a high absorbency value (k) at a specified wavelength, thus, minimizing reflection.

A method for forming a tunable dielectric antireflective layer for image transfer processing in accordance with the principles of the present invention includes forming a first layer on a surface, forming a second layer on the first layer, the second layer being a light sensitive layer, and tuning the index of refraction of the first layer to match the index of refraction of the second layer by a predetermined annealing process.

A tunable dielectric antireflective layer for image transfer processing in accordance with the principles of the present invention includes a first layer, a second layer formed on the first layer, the second layer being a light sensitive layer, and the first layer having an index of refraction selected to match the index of refraction of the second layer using a predetermined annealing process.

A thin film magnetic head in accordance with the principles of the present invention is formed by a method including forming a first layer on a surface, forming a second layer on the first layer, the second layer being a light sensitive layer, and the first layer having an index of refraction selected to match the index of refraction of the second layer using either baking or electron beam curing.

A storage device in accordance with the principles of the present invention includes at least one data storage medium mounted for simultaneous rotation about an axis, at least one magnetic head mounted on an actuator assembly for reading and writing data on the at least one data storage medium, and an actuator motor for moving the at least one magnetic head relative to the at least one data storage medium, wherein the head is formed using a photoresist process and wherein at least one stage in the photoresist process includes forming a tunable dielectric antireflective layer for image transfer processing, including forming a first layer on a surface, forming a second layer on the first layer, the second layer being a light sensitive layer, and tuning the index of refraction of the first layer to match the index of refraction of the second layer using a predetermined annealing process.

These and various other advantages and features of novelty which characterize the invention are pointed out with particularity in the claims annexed hereto and form a part hereof. However, for a better understanding of the invention, its advantages, and the objects obtained by its use, reference should be made to the drawings which form a further part hereof, and to accompanying descriptive matter, in which there are illustrated and described specific examples of an apparatus in accordance with the invention.

### BRIEF DESCRIPTION OF THE DRAWINGS

Referring now to the drawings in which like reference numbers represent corresponding parts throughout:

FIG. 1 is a graph of swing curves showing the change in reflectivity in various ARC coatings;

FIG. 2 is a graph that compares the reflectivity of certain metal oxide hardmasks with respect to the metal oxide hardmask's varying thickness;

FIG. 3 illustrates a structure having a spin-on-glass material that can act as both a hardmask and deep-UV bottom anti-reflection layer (BARC) according to the present invention;

FIG. 4 is another embodiment of a hardmask and deep-UV bottom anti-reflection layer (BARC) structure including a release layer according to the present invention;

FIGS. 5a and 5b illustrate the developing and etching process using a BARC/hardmask structure according to the present invention;

FIG. 6 is a flow chart of a process for creating tunable deep-UV dielectric anti-reflective layers according to an embodiment of the present invention;

FIG. 7 is a table illustrating the results of tuning a composition by a thermal or E-beam annealing process to produce various n and k values;

FIG. 8 is a sensor and write element, which may be formed using the method of the present invention; and

FIGS. 9a-f illustrate an alternative image transfer process for producing high aspect ratio plated features according to the present invention.

### DETAILED DESCRIPTION OF THE INVENTION

In the following description of the exemplary embodiment, reference is made to the accompanying drawings, which form a part hereof, and in which is shown by way of illustration the specific embodiment in which the invention may be practiced. It is to be understood that other embodiments may be utilized as structural changes may be made without departing from the scope of the present invention.

The present invention is a photolithographic technique used in image transfer processing. More particularly, the present invention is a tunable deep-UV dielectric antireflective layer and use thereof.

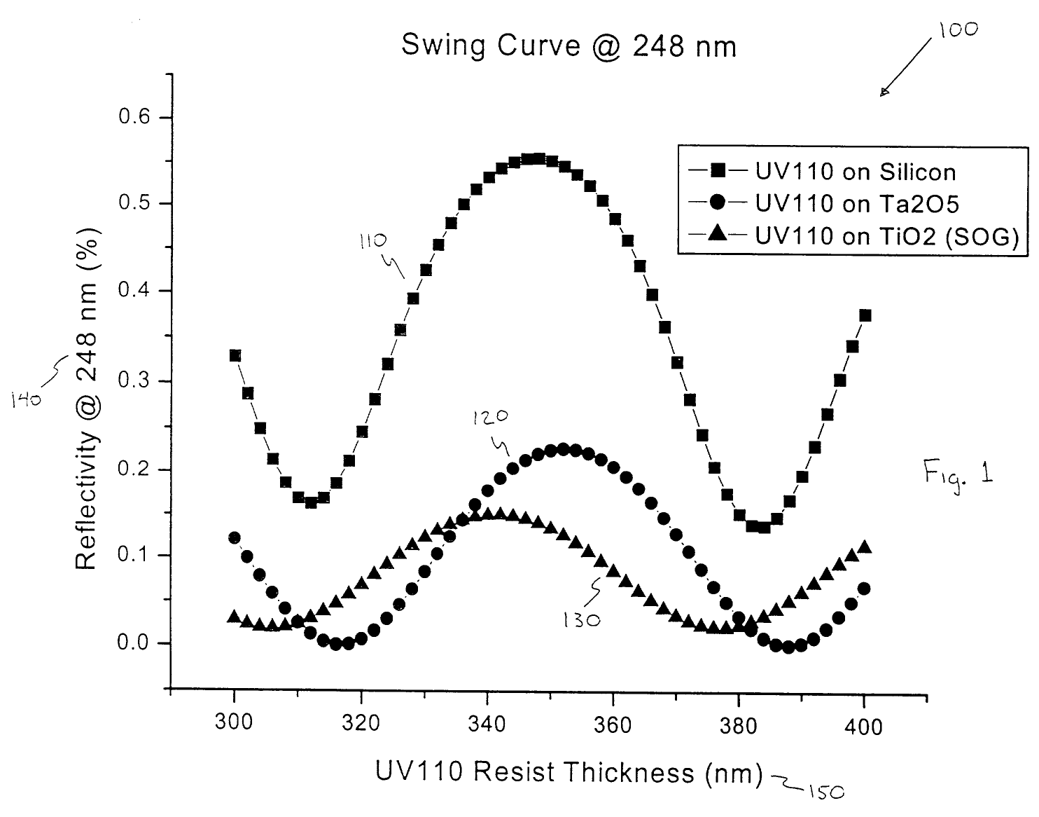

FIG. 1 is a graph 100 of swing curves showing the change in reflectivity in various ARC coatings. The presence of a substrate underneath a photoresist (resist) has a significant effect on the light intensity distribution within the photoresist film. Rapid sinusoidal variations of light intensity within the photoresist, resulting from reflected and incident components of the light, may cause a standing wave effect. The consequence of the standing waves of light intensity throughout the photoresist are visible in photoresist features, for example, the sidewalls of the photoresist develop a ridged appearance.

In addition to the standing wave throughout the depth of the photoresist, the amount of light absorbed in the photoresist is functionally dependent on the thickness of the substrate and photoresist films. Accordingly, antireflection coatings (ARC) are used to minimize standing waves and maximize resolution in I-line and DUV processes. An optimal ARC includes a matching refractive index (n), some absorbance (k) and appropriate film thickness to minimize reflections at the ARC-resist interface, thus, minimizing the overall photoresist swing curve. The effect of reflectivity occurring from a resist-ARC topology in a lithography process may be further understood using a swing curve graph 100 illustrating the reflectivity of light at a particular wavelength with reference to the thickness of a photoresist.

Thin-film interference effects induced by coating nonuniformities induced by the photoresist can cause large variations in the energy coupled into the photoresist, resulting in a linewidth dependence on photoresist thickness. This so-called swing curve effect, whether from a nonuniform photoresist application or the result of local variations in the chip topography, can translate into large linewidth variations. In addition, as mentioned above, standing waves can be established in the photoresist that will cause photoresist profile deformation. In addition, scattering light from underlying topography can be a cause of linewidth variations. Thus, a thin film imaging (TFI) system that is insensitive to variations in photoresist thickness and substrate reflectivity therefore has a decided advantage.

The use of anti-reflective coatings decreases the change in reflectivity from the photoresist with changes in photoresist thickness. The swing curve graph 100 illustrates the swing curves for silicon (Si) 110, tantalum oxide (Ta₂O₅) 120, and titanium oxide (TiO₂) 130 on a UV110™ photoresist. The graph 100 illustrates that the reflectivity at a wavelength of 248 nm 140 is minimized by the change in substrate and/or coatings 110, 120, 130 throughout the photoresist thickness 150.

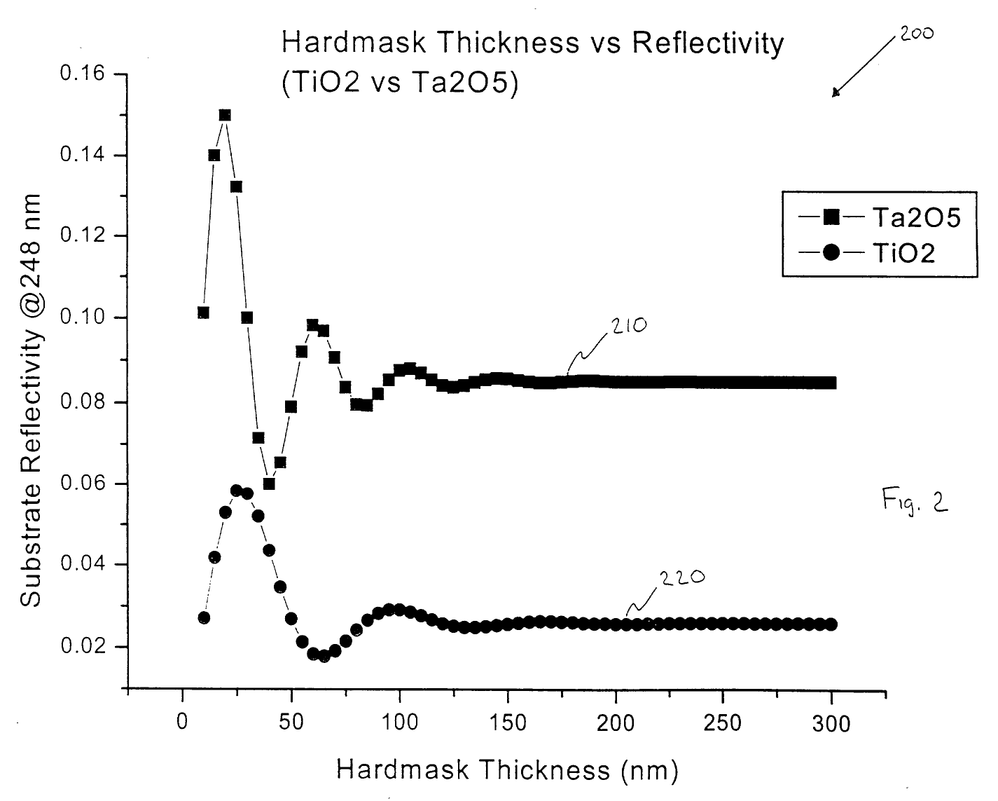

FIG. 2 is a graph 200 that compares the reflectivity of certain metal oxide hardmasks with respect to the metal oxide hardmask's varying thickness. A metal oxide hardmask, such as Ta₂O₅ and SiO₂ glass may be interposed between a substrate and a photoresist layer. The SiO₂ may be applied as a SOG or through sputter or CVD deposition and Ta₂O₅ may be applied via a CVD process. The glass intermediate, or barrier, layer serves two functions: first, it may prevent the formation of an interfacial layer due to mixing of layers above and below the glass, and second, it acts as an intermediate etch-mask in the transfer of the pattern into the bottom layer by reactive ion etching (RIE).

However, current image transfer processes using these conventional metal oxide hardmask (e.g., Ta₂O₅ (210) or SiO₂) are either highly reflective at a wavelength of 248 nm or have a poor refractive index (n) match (i.e., for tantalum oxide n is 2.94, for silicon dioxide n is 1.5) with conventional photoresists (n=1.7-1.8).

The present invention uses a spin-on-glass (SOG) material that can act as both a hardmask and a deep-UV antireflective layer (BARC). One such material is a titanium oxide (TiO₂) 220, which is generated by spin-coating an alkyl titanium followed by an annealing (e.g., curing) process (either heat or electron beam alone or in some combination). The complex index of refraction can be “tuned” to match index of refraction, n, to the photoresist along with a high enough absorbancy value, k, to minimize reflections at a given wavelength, such as 248 nm.

TiO₂ SOG 220 material is generally stable in solution and can be applied on a track and baked with a hot-plate. The film thickness can be adjusted by varying the concentration of the formulation or by changing the spin-speed of the coater. The tooling already is readily available in the manufacturing line and the material is commercially available or can be prepared by an easy one-step process. Baking or e-beam curing can create n values from approximately 1.65-2.1 and k values from approximately 0.35 to 0.80. Modeling programs, such a PROLITH™, predicts that the substrate reflectivity is reduced to below 4%. Etching studies with CF4 gas gave etch rates near 10-20 Å/sec whereas in O₂ gas the etch rate is reported to be close to zero. This allows for a selective etch ratio of hardmask to organic underlayers.

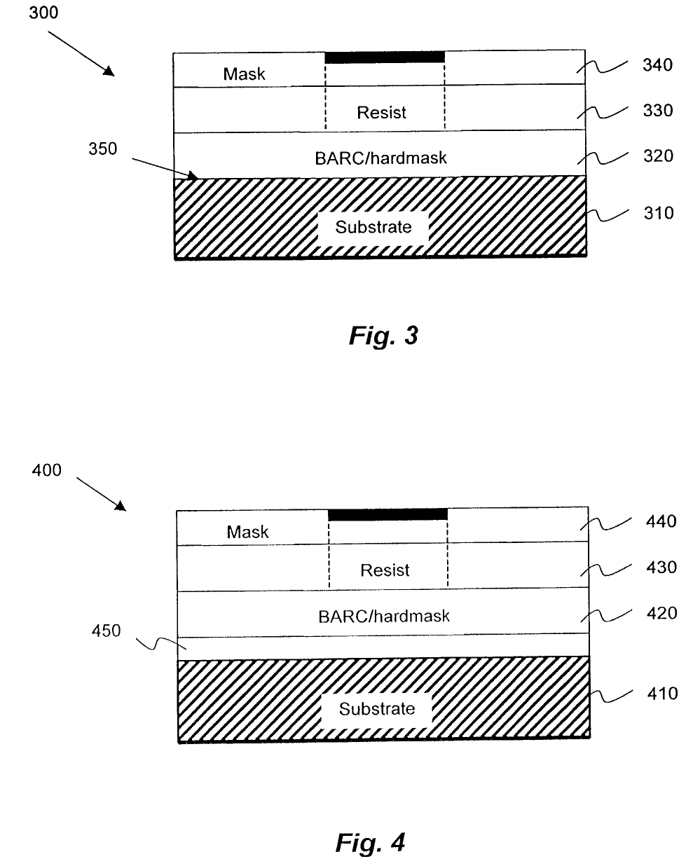

FIG. 3 illustrates a structure 300 having a spin-on-glass material that can act as both a hardmask and deep-UV bottom anti-reflection layer (BARC) according to the present invention. Anti-reflection coatings, usually a polymer or glass, are applied upon a surface 350 of a substrate 310 to reduce the reflectance from that substrate surface 350. Antireflection coatings typically include an assembly of thin film layers of different coating materials applied to the substrate surface 350 in selected sequence.

The difference in the index of refraction of a coating material, or the effective index of refraction for a combination of material layers, and the index of refraction of the substrate material affects the amount of reflectance at the substrate surface 350. In addition to the difference in the indices of refraction of the coating and substrate materials, the amount of reflectance is affected by numerous other factors including the intensity, the wavelength, and the angle of the incident light, as mentioned above. Other properties of anti-reflection coating material or materials including the thickness, the optical constants, and the specularity, also affect the amount of reflectance. An ideal antireflection coating for a particular application would demonstrate zero reflectance for the imaging wavelength range used.

A simple antireflection coating may comprise a single layer of a material having a refractive index between the refractive indices of the medium through which reflection will occur and the interfacing substrate material. The index of refraction value varies with wavelength.

More commonly, antireflection coatings comprise multiple layers of at least two different materials applied to a substrate surface 350. The innermost layer of the antireflection coating, i.e., the layer positioned adjacent the substrate surface 350, typically comprises a material having a high index of refraction, i.e., preferably greater than 1.8 and, most preferably, greater than 2. Suitable materials may include various metal oxides such as TiO₂, ZrO₂, Nb₂ O₅, Ta₂ O₅, ZnO₂, In₂ O₃, SnO₂, and HfO₂ as well as alloys of these metal oxides.

BARCs address most of the problems associated with reflective substrates including standing waves within the photoresist film, problems of notching, control of critical dimensions with exposure dose and linewidth variations over topography. A BARC may be formed on a substrate 310, before the deposition of a photoresist 330, to prevent the reflection of light that passes through the photoresist 330 and is reflected off the substrate 310, or other reflective features, and back into the photoresist 330, where the light reflected off the substrate 310 can interfere with incoming light and cause the photoresist 330 to be unevenly exposed. As industry transitions to light with shorter wavelengths, e.g., from 248 nm, 193 nm, 157 nm and below, the challenges of minimizing reflections increase. Accordingly, as the wavelengths become shorter, the reflectivity of the substrate becomes higher, and as a result, there are more problems with interference effects that affect the ability to get consistency in photoresist patterns.

One embodiment of the present invention resolves the problem by providing a spin-on-glass material having properties of both hardmask and deep-UV bottom anti-reflective layer (BARC/hardmask) 320 to minimize pattern distortion. The BARC/hardmask 320 minimizes critical dimensions and exposure variations due to photoresist thickness (swing curve) effects. However, to be effective a BARC/hardmask 320, the BARC/hardmask 320 must have appropriate complex refractive index (ñ=n+ik, wherein n+ik is the real and imaginary parts of the complex refractive index ñ) and thickness so that reflections between substrate 310 and photoresist 330 are fully damped.

In an embodiment of the present invention, a BARC/hardmask 320 is formed by a material that will act as both a hardmask and a BARC, for example a titanium oxide such as TiO₂ (and other metal oxides and their alloys), in which the titanium oxide is generated by spin-coating an alkyl titanium and curing the film by heat or electron beam. The BARC/hardmask 320 material can be “tuned” to match index of refraction, n, to the photoresist and also contain a high absorbency value, k, at a specific wavelength, such as 248 nm. For example, the BARC/hardmask material 320 film thicknesses can be adjusted by varying the concentration of the formulation or by changing the spin-speed of the coater. Baking or e-beam curing can create n values from approximately 1.78-2.1 and k values from approximately 0.59 to 0.80. Modeling programs, such as PROLITH™, predicts substrate reflectivity to be reduced below 4%. Etching studies with CF4 gas gave etch rates near 10-20 Å/sec whereas in O₂ gas the etch rate is reported to be zero. This allows for a selective etch ratio of hardmask to organic underlayers.

Thus, the aforementioned structure creates a tunable BARC that matches the n of the photoresist and has a high k value the trackwidth control will be improved. At the same time the material can act as a hard mask, which is highly resistant to oxygen etch (e.g., used in etching organic films) but can be etched with conventional CxFy gases. This material can be a cost-effective alternative BARC/hardmask for image transfer with DUV photoresists.

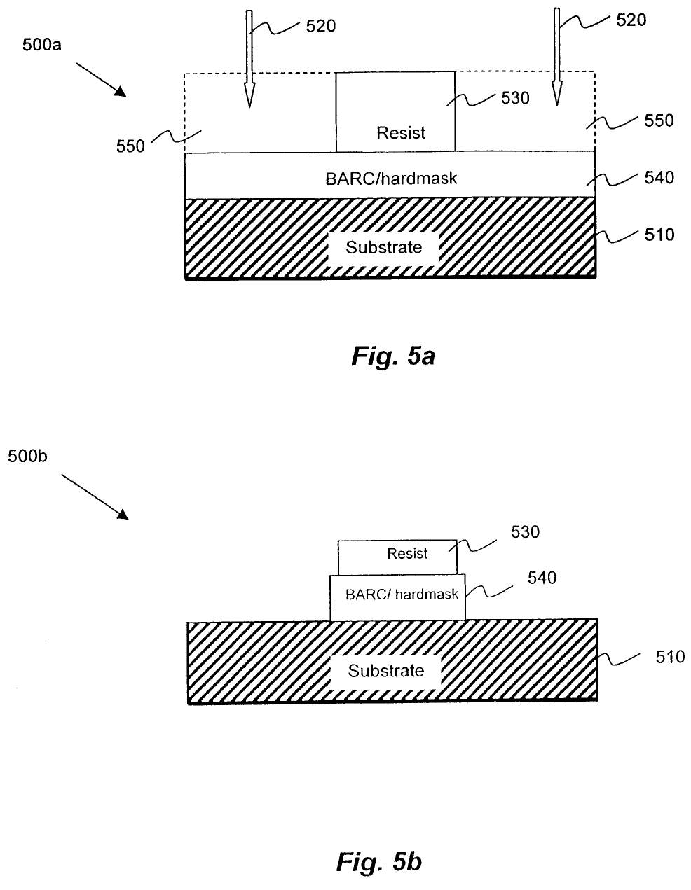

FIG. 4 is another embodiment of a hardmask and deep-UV bottom anti-reflection layer (BARC) structure 400 including a release layer according to the present invention. An application of the BARC/hardmask 420 with the titanates as a spin-on-glass (SOG), further employing a release layer 450, is described below. A SOG 420 can be coated upon a previously cast and baked underlayer (release layer) 450 which can be stripped in organic solvent such as N-methyl-pyrrolidone (NMP). The release layer 450 can include a material, which after baking, will not readily intermix with a second casting layer (SOG) 420. Such materials may include lightly cross-linked novolak, soluble polyimide polyetherimides, polydimethlyglutarimide (PMGI) or polyarylsulfones.

All the above release materials may be used as a thin film (150-1000 Å), and after subsequent processing would be removed by hot NMP (i.e., subsequent processing is (1) Apply release layer; (2) apply SOG and bake/or cure; (3) apply photoresist; (4) image/develop photoresist; (5) CxFy RIE of SOG; (6) oxygen RIE of release layer; and (7) removal of metalized photoresist materials). This process can be used in a metal liftoff process such as used in defining a GMR sensor in TFH processing.

FIGS. 5a and 5b illustrate a developing and etching process using a BARC/hardmask structure 500a, 500b according to the present invention. FIG. 5a illustrates a structure 500a that is formed by a lithography process. The process typically involves controlled actinic light 520 (exposure light; e.g., ultraviolet (UV) or deep-ultraviolet (DUV) radiation), which is projected onto a photolithographic mask (FIG. 4, 440) in order to transfer a pattern onto a layer of light-sensitive material, such as a photoresist 530, deposited on a substrate 510. The mask (FIG. 4, 440) typically embodies a light transmissive substrate with a layer of light blocking material defining the patterns of circuit features to be transferred to a photoresist-coated substrate.

When a positive photoresist 530 is used, as illustrated in FIG. 5a, the exposure light 520 passing through the mask (FIG. 4, 440) will cause the exposed portions of the photoresist layer 550 to become soluble to a developer, such that the exposed photoresist layer 550 portions will wash away in the development step leaving a desired pattern of photoresist material corresponding directly to the mask pattern.

Alternatively, if a negative photoresist (not shown) is used, then the projected exposure light 520 passing through the mask (FIG. 4, 440) will cause the exposed areas of the photoresist layer 550 to undergo polymerization and cross-linking, resulting in an increased molecular weight. In a subsequent development step, unexposed portions of the photoresist layer 530 will wash off with the developer, leaving a pattern of photoresist material constituting a reverse or negative image of the mask pattern.

FIG. 5b illustrates a two-step RIE process on a structure 500b according to the present invention. In the first step, the BARC/hardmask 540 layer, which is a thermally cured SOG film that is highly resistant to O₂ RIE, is etched with a CxFy gas, such as CF4 gas. Etching with a CxFy gas results, for example, in etch rates of nearly 10-20 Å/sec, whereas an O₂ gas the etch rate is substantially zero. The CxFy etch transfers the photoresist pattern to the BARC/hardmask 540 layer. The second step uses O₂ RIE, transferring the pattern to the substrate 510, further removing the BARC/hardmask 540 layer. This two-step process allows for a selective etch ratio of hardmask to organic underlayers.

In general, by creating a tunable BARC/hardmask layer 540, which matches the n of the photoresist and has a high k value, the trackwidth control will be improved, for example, in TFH fabrication. At the same time the BARC/hardmask 540 material can act as a hard mask that is impervious to oxygen etch (e.g., used in etching organic films), but can be etched with conventional CxFy gases. This material can be a cost-effective alternative BARC/hardmask for image transfer with DUV photoresists.

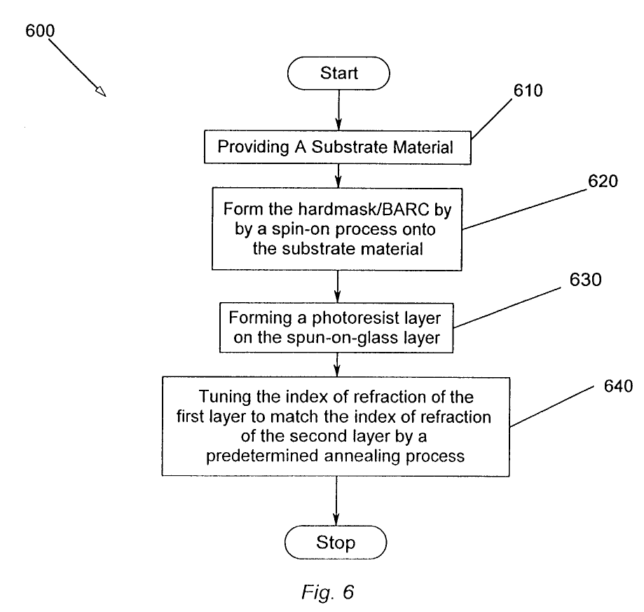

FIG. 6 is a flow chart of a process for creating tunable deep-UV dielectric anti-reflective layers 600 according to an embodiment of the present invention. A substrate is provided 610 on which a SOG material, which can act as both a hardmask and deep-UV bottom anti-reflective coating, is applied (BARC/hardmask layer) 620. The photoresist layer is then deposited on the BARC/hardmask layer by any well-known manner 630. The BARC/hardmask layer thickness may be adjusted by varying the concentration of the formulation of by changing the spin speed of the coater. This adjustment varies the thickness of the SOG thereby selecting a minima of reflectivity. The BARC/hardmask layer is baked or can be optionally electron beam cured 640. The baking step is needed to remove casting solvent. Furthermore baking or e-beam exposure is used to both cure and “tune” the optical properties (n) of the resultant titanate film so as, for example, to match the at least one of these properties of the BARC/hardmask layer to that of a photoresist.

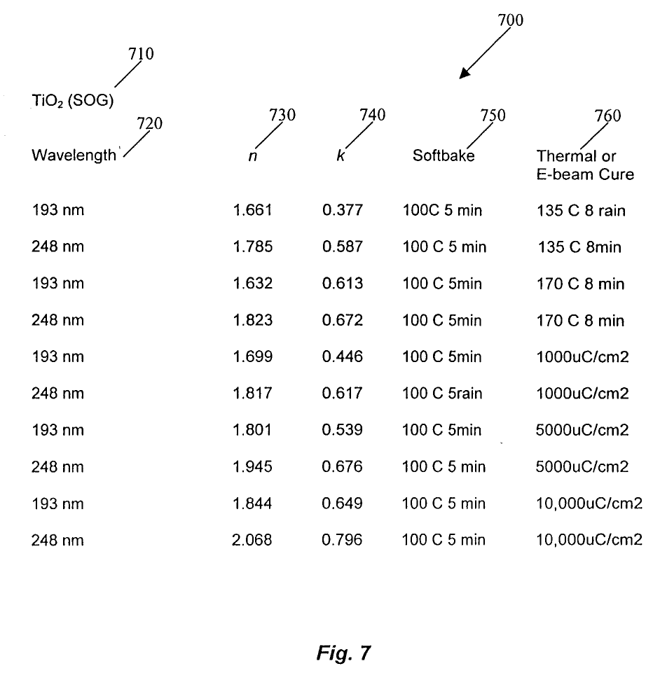

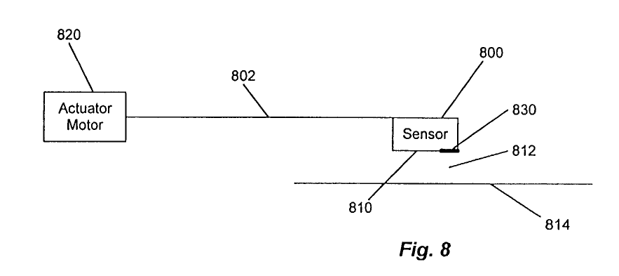

FIG. 7 is a table 700 illustrating the results of tuning a composition by a thermal or E-beam annealing process to produce various n and k values. The table 700 illustrates that specific refractive indexes (n) 730 and absorbance (k) 740 values can be produced for a particular wavelength 720 using thermal or e-beam curing 760 in the annealing process. The values for n 730 and k 740 are produced by first softbaking 750 a composition (e.g., alkyl titanate such as TiO₂ 710) for a predetermined period of time and then thermal or e-beam curing 760 the composition for a predetermined period of time.

By tuning the refractive index (n) with the e-beam or thermal process 760, the refractive indices (n) 730 of the composition will more closely match the refractive index of the photoresist for example, and as a consequence, less bending of light and reflectivity between the BARC composition and the photoresist layers.

With reference now to FIG. 8, there is depicted a schematic view of a sensor and write element which may be formed using the method of the present invention. As illustrated, FIG. 8 depicts a plan view of the air-bearing surface of a sensor 800 (e.g., a GMR head, MR head, tape head, etc.) having a write element poll tip 830. The air-bearing surface 810 of the sensor is mounted to a suspension or other mounting 802 and normally rides on a cushion of air 812, which separates it from a magnetic data storage medium 814, such as a disk or tape. The motion of the sensor 800 is controlled by an actuator motor 820 coupled to the mounting 802.

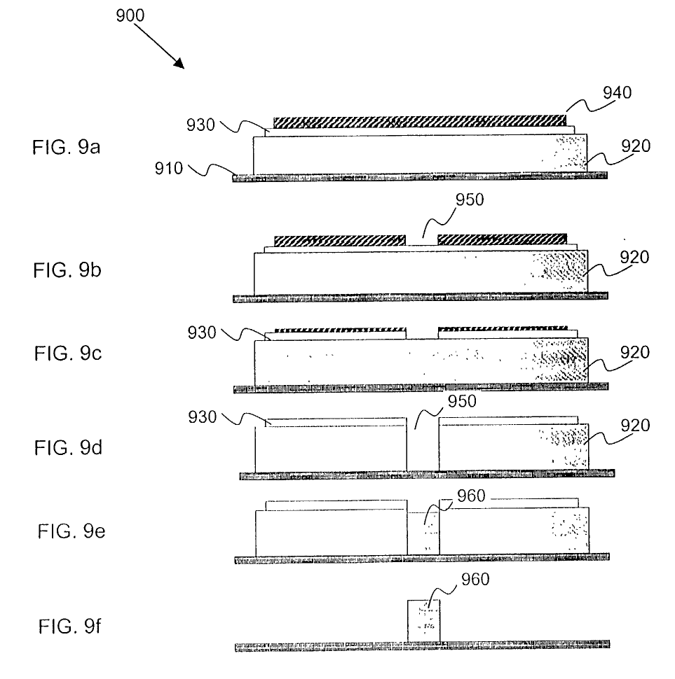

FIGS. 9a-f illustrate an alternative image transfer process 900 for producing high aspect ratio plated features according to the present invention. In FIGS. 9a-f, a spin-on alkyl titanate, for example, can be use in an image transfer process to produce a high aspect ratio plated feature. The spin-on process can replace a currently used sputter-deposited hardmask, such as Ta₂O₅. Further, this process can be used, for example, in producing the top pole piece (writer) of a thin film magnetic head (spin valve or GMR).

In FIG. 9a a thin film hardmask 930 (e.g., 1000-2000 A) is placed upon a thick film polymer 920, such as novolak (e.g., 4-5 um), the polomer 920 may be deposited on a substrate 910. The top surface of the hardmask 930 is coated with a film of photoresist 940 (i.e., i-line or deep-ultraviolet sensitive). The photoresist 940, for example, may be exposed and developed as an isolated trench feature 950 as illustrated in FIG. 9b. FIG. 9c shows the exposed hardmask 930 selectively RIE etched with a CxFy chemistry, for example, wherein the polomer underlayer 920 is not etched.

FIG. 9d illustrates a following selective RIE etch step using oxygen (or some combination of oxygen/CF₄, for example), which etches only the polomer 920 (e.g., novolak) underlayer as a deep tench feature 950, wherein the critical dimension of the feature is transferred from the dimension on the etched hardmask 930. FIG. 9e illustrates the high aspect ratio (10-20:1) trench feature 950 being plated with a high moment magnetic material 960 (e.g., Ni—Fe alloy). FIG. 9f illustrates the plated feature 960 that is stripped free of organic and passivant residue with either a dry or wet etch step.

The foregoing description of the exemplary embodiment of the invention has been presented for the purposes of illustration and description. It is not intended to be exhaustive or to limit the invention to the precise form disclosed. Many modifications and variations are possible in light of the above teaching. It is intended that the scope of the invention be limited not with this detailed description, but rather by the claims appended hereto.

What is claimed is:

1. A method for forming a tunable dielectric antireflective layer for image transfer processing, comprising:
forming a first layer on a surface;
forming a second layer on the first layer, the second layer being a light sensitive layer; and
tuning the index of refraction of the first layer to match the index of refraction of the second layer using a predetermined annealing process.

2. The method of claim 1, wherein the forming the first layer further comprises forming a spin-on-glass material.

3. The method of claim 2, wherein the spin-on-glass material includes metal alkoxylates containing alkyl titanates.

4. The method of claim 3 further comprising compositions including double metal alkoxylates containing titanate.

5. The method of claim 2, wherein the spin-on-glass material includes compositions including double metal alkoxylates containing titanate.

6. The method of claim 1, wherein the forming the second layer further comprises forming a hardmask and an antireflection layer.

7. The method of claim 1, wherein the forming the first layer further comprises forming a metal oxide layer.

8. The method of claim 1, wherein the forming the first layer further comprises providing a high absorbency value, k, at a selected wavelength.

9. The method of claim 1, wherein forming the first layer further comprises spin-coating an alkyl titanate on the surface and curing the coating.

10. The method of claim 9, wherein curing the coating further comprises curing the coating with heat or electron beam.

11. The method of claim 1 further comprising exposure of the second layer with ultraviolet light.

12. The method of claim 1 further comprising forming a third layer between the surface and the first layer

13. The method of claim 12, wherein the third layer can be removed by an organic solvent, wherein the third layer is processed to provide an undercut profile for a subsequent metalization step allowing the first and second layers to be removed in a metal liftoff scheme.

14. The method of claim 1 wherein the forming of the first layers is accomplished by a vacuum deposition process.

15. The method of claim 1, wherein the tuning of the complex index of refraction of the first layer to the index of refraction of the second layers minimizes reflection.

16. A tunable dielectric antireflective layer for image transfer processing, comprising:
a first layer;
a second layer formed on the first layer, the second layer being a light sensitive layer; and
the first layer having an index of refraction selected to match the index of refraction of the second layer using a predetermined annealing process.

17. The tunable dielectric antireflective layer of claim 16, wherein the first layer further comprises a spin-on-glass material.

18. The tunable dielectric antireflective layer of claim 17, wherein the spin-on-glass material includes metal alkoxylates containing alkyl titanium.

19. The tunable dielectric antireflective layer of claim 18 further comprising compositions including double metal alkoxylates containing titanate.

20. The tunable dielectric antireflective layer of claim 17, wherein the spin-on-glass material includes compositions including double metal alkoxylates containing titanate.

21. The tunable dielectric antireflective layer of claim 16, wherein the forming the second layer further comprises forming a hardmask and an antireflection layer.

22. The tunable dielectric antireflective layer of claim 16, wherein the first layer provides a high absorbency value, k, at a selected wavelength.

23. The tunable dielectric antireflective layer of claim 16, wherein the first layer is a spun-on-coating comprising a titanium alkanate cured on the surface.

24. The tunable dielectric antireflective layer of claim 23, wherein the spun-on-coating is cured with heat or electron beam.

25. The tunable dielectric antireflective layer of claim 16, wherein the second layer is exposed by deep ultraviolet light.

26. The tunable dielectric antireflective layer of claim 16, further comprising a third layer is formed between the surface and the first layer.

27. The tunable dielectric antireflective layer of claim 26, wherein the third layer can be stripped in an organic solvent, wherein the third layer is processed to provide an undercut profile for a subsequent metalization step allowing the first and second layers to be used in a metal liftoff scheme.

28. The tunable dielectric antireflective layer of claim 16 wherein the first layers is formed by a vacuum deposition process.

29. The tunable dielectric antireflective layer of claim 16, wherein the index of refraction for the first and second layers are matched to minimize reflection.

30. A thin film magnetic head formed by a method comprising:
forming a first layer on a surface;
forming a second layer on the first layer, the second layer being a light sensitive layer; and
the first layer having an index of refraction selected to match the index of refraction of the second layer by either baking or electron beam curing.

31. The thin film magnetic head formed by the method of claim 30, wherein the forming the first layer further comprises forming a spin-on-glass material.

32. The thin film magnetic head formed by the method of claim 30, wherein the forming the second layer further comprises forming a hardmask and an antireflection layer.

33. A storage device, comprising:
at least one data storage medium mounted for simultaneous rotation about an axis;
at least one magnetic head mounted on an actuator assembly for reading and writing data on the at least one data storage medium;
an actuator motor for moving the at least one magnetic head relative to the at least one data storage medium; and
wherein the head is formed using a photoresist process and wherein at least one stage in the photoresist process includes forming a tunable dielectric antireflective layer for image transfer processing, the tunable dielectric anti-reflective layer comprising:
forming a first layer on a surface;
forming a second layer on the first layer, the second layer being a light sensitive layer; and
tuning the index of refraction of the first layer to match the index of refraction of the second layer using a predetermined annealing process.
